(19) United States
(12) Patent Application Publication
(10) Pub. No.: US 2014/0132280 A1
(43) Pub. Date: May 15, 2014

(54) Method And Device For Monitoring A Test Interval For A Residual Current Protective Device

(71) Applicant: Bender GmbH & Co. KG, Gruenberg (DE)

(72) Inventor: Dieter Hackl, Fernwald (DE)

(73) Assignee: Bender GmbH & Co. KG, Gruenberg (DE)

(21) Appl. No.: 14/076,968

(22) Filed: Nov. 11, 2013

(30) Foreign Application Priority Data
Nov. 13, 2012 (DE) 10 2012 220 692.2

(51) Int. Cl. G01R 31/327

(52) U.S. Cl. CPC G01R 31/327
USPC 324/550

(57) ABSTRACT

A method and device for monitoring a test interval for a residual current protective device includes measuring an operating time of the residual current protective device, triggering an alarm report if the measured operating time exceeds an operating time limit, and restarting the operating time measurement upon detection of a trigger process of the residual current protective device. In an embodiment of the invention, a time period is measured independent of the operating time of the residual current protective device.

### CROSS-REFERENCE TO RELATED APPLICATIONS

This application claims priority to German Patent Application No. 10 2012 220 692.2 filed on Nov. 13, 2012, which is fully incorporated herein by reference.

### STATEMENT REGARDING FEDERALLY SPONSORED RESEARCH OR DEVELOPMENT

Not applicable.

### FIELD OF THE INVENTION

The invention relates to a method for monitoring a test interval for a residual current protective device and to a device for maintaining the test interval.

### BACKGROUND OF THE INVENTION

For protection in case of contact to bodies of electrical equipment, the use of residual current protective devices (RCDs) is known as a protective measure in electrical systems; their use is set out in safety standards. The mode of action of such residual current protective devices is based on the fact that in the faultless operation of an electrical system, the vectorial sum of the currents on all current-carrying conductors of a supply line is zero and thus there is no magnetic field in the surrounding of the supply line. If, owing to an insulation fault, a residual current occurs, which outside of the supply line flows into a body or into earth, a differential current arises. For the purpose of detecting the differential current, all active conductors of the line to be protected are guided as a primary winding through a measuring current transformer core which is provided with a secondary winding. If, for example as a consequence of an insulation fault, a residual current flows to earth, a differential current flows through the measuring current transformer, the magnetic field of said differential current inducing a voltage on the secondary side in case of a temporal change, said voltage causing a secondary current that triggers a switching member which separates the faulty supply line.

The reliable function of the residual current protective device throughout the entire product life and the accompanying effectiveness in the context of a protective concept depends on the temporal constancy of the mechanical and electrical properties of the components installed in the residual current protective device. However, this required temporal constancy cannot be guaranteed by the manufacturers of residual current protective devices so that a test key is provided upon actuation of which an artificial residual current is generated, which causes the triggering of the residual current protective device.

According to accident prevention regulation BGV A3 for electrical systems and equipment, said test key is to be actuated regularly in the course of a repetitive test, the test interval being 6 months in stationary systems and an interval of one test per workday being specified in non-stationary systems.

In a plurality of the residual current protective devices installed in an electrical system, compliance with these regulations requires an extensive planning effort for the performance of these maintenance and testing activities. Experience shows that it can be assumed that the implementation of this accident prevention regulation is carried out properly in the sector of large companies and medium-sized enterprises, but is neglected in small companies and especially in the private sphere. Up to now, the technical problem of securing the functionality of a residual current protective device was addressed merely by a more or less successful autonomous planning and implementation of the repetitive tests. Thus, it can be assumed that a certain number of residual current protective devices are in use that no longer function correctly, but on whose effectiveness a safety concept for the respective electrical system is still based.

Therefore, it is the task of the present invention to help maintain the proper state and thus the functionality of a residual current protective device throughout the entire product life by applying a suitable method and by means of a corresponding device.

### SUMMARY OF THE INVENTION

The task is solved in a first embodiment of the invention by a method for monitoring a test interval for a residual current protective device comprising the repeatedly performed method steps of measuring an operating time of the residual current protective device, triggering an alarm report if the measured operating time exceeds an operating time limit and restarting the operating time measurement upon detection of a trigger process of the residual current protective device.

The underlying idea of the present invention is based on indicating to the operator of the electrical system in good time that a test interval is expiring. This preferably takes place by measuring the operating time of the residual current protective device in connection with triggering an alarm report if the measured operating time exceeds an operating time limit. Monitoring the test interval on the basis of the measurement of the operating time ensures that the required test intervals for the residual current protective device are maintained and thus the effectiveness of a protective concept for the electrical system is guaranteed. Independently of the sending out of the alarm report, the measurement of the operating time is restarted upon detection of a trigger process of the residual current protective device in order to be able to monitor the next test interval.

In a further implementation of the first embodiment of the method, a line voltage is measured on a supply side and a line voltage is measured on a load side of the residual current protective device and the restart of the operating time measurement takes place as a function of the measured line voltages. The operating time measurement is automated to the effect that a reset and thus a restart of the operating time measurement take place as a function of the measured line voltages. For this purpose, the respective line voltages are measured on the supply side and on the load side of the residual current protective device to be tested. As a function of the measured values, a restart of the operating time measurement is carried out so that the monitoring of the temporally subsequent test interval is triggered. The moment of the restart thus results as a function of the measured line voltages. If the latter meet certain conditions, a restart of the operating time measurement is initiated.

Advantageously, the restart of the operating time measurement takes place if an evaluation of the measured line voltages reveals that the line voltage on the supply side has the value of the nominal system voltage and the nominal system voltage on the load side is switched off. Hence, if a comparison of the measured line voltages shows that there is no load-side line voltage while a nominal system voltage is present at the supply side, it can be assumed that a triggering of the residual current protective device has taken place, which means that the functionality thereof was ensured at that point in time. After that, the temporally subsequent test interval can be monitored by restarting the operating time measurement.

It has proven practical for the operating time limit to be adjustable. Owing to the adjustability of the operating time limit, the operating time measurement can be adjusted to required test intervals. For instance, by means of a corresponding adjustment of the operating time limit, the expiring 6-monthly test interval for stationary systems can be announced in good time with regard to the repetitive tests prescribed by the accident prevention regulation BGV A3. Likewise, it is possible by means of the invention to monitor a daily test interval for non-stationary systems, for example, by adjusting the operating time limit to a smaller value.

The basic task is solved in an alternative, second embodiment of the invention by a method for monitoring a test interval for a residual current protective device, comprising the repeatedly performed method steps of: measuring a time period that is independent of the operating time of the residual current protective device, triggering an alarm report if the measured time period exceeds a time period limit and restarting of the time measurement upon detection of a trigger process of the residual current protective device.

This variation, too, is based on the thought of indicating to the operator of the electrical system in good time that a test interval is expiring, whereas, in this case, it is not the operating time of the residual current protective device that is used as the reference value, but a time measurement that is independent of the operating time of the residual current protective device. All that must be available is (some kind of) a time scale. If on said time scale a time period limit is exceeded, a triggering of an alarm report is caused.

In order to monitor a temporally subsequent test interval, a restart of the time measurement takes place independently of the sending out of the alarm report as soon as a trigger process of the residual current protective device is detected.

Preferably, vibrations of components of the residual current protective device are detected for detecting the trigger process of the residual current protective device, said vibrations occurring in connection with the trigger process. In contrast to the first embodiment, in this second embodiment, a detection of the trigger process of the residual current protective device takes place that is independent of the line voltage, and thus also a measurement of the time period takes place that is independent of the operating time of the residual current protective device. Since in each trigger process of the residual current protective circuit components of the residual current protective circuit are caused to vibrate, said component vibrations can be detected by suitable vibration detectors and be used for detecting the trigger process.

With the detection of the trigger process independent of the system voltage, types of disruptions can be taken into account which are purely time-dependent and not voltage-dependent, such as the gumming of lubricants used in the residual current protective device.

Advantageously, the time period limit is adjustable so as to meet different requirements concerning the prescribed test intervals in this embodiment as well.

In both embodiments, an acoustically and/or optically perceptible signal can be sent out as the alarm report in order to indicate the upcoming repetitive test in time to the operator of the electrical system.

Further, it is advantageous that when triggering an alarm report, a switching contact is actuated and/or a wired interface and/or a wireless interface is activated. In this manner, the alarm report indicating an upcoming repetitive test can be transmitted to respective places for further measures to be taken.

With regard to a device, the task is solved by a monitoring device for maintaining a test interval for a residual current protective device, the monitoring device comprising an operating time counter for measuring an operating time of the residual current protective device and a limit comparator for detecting an exceedance of an adjustable operating time limit and for sending out a trigger signal for an alarm report.

Corresponding to the method according to the invention in the first embodiment, the monitoring device of the invention comprises an operating time counter which measures the operating time of the residual current protective device and whose counter reading is proportional to the operating time of the residual current protective device since the last restart (reset). The counter reading of the operating time counter is compared by a limit comparator to a preset operating time limit. If the operating time limit is exceeded, the limit comparator sends out a trigger signal for an alarm report.

In an advantageous implementation, the monitoring device comprises a voltage detector for detecting a line voltage on a supply side of the residual current protective device and a difference detector for detecting a difference in the line voltages between the supply side and a load side of the residual current protective device and for generating a reset signal for the operating time counter.

The voltage detector detects the line voltage on the supply side of the residual current protective circuit and enables the counting process of the operating time counter. The difference detector receives a status signal form the voltage detector concerning the line voltage present on the supply side and at the same time it tests the line voltage on the load side. If the test reveals that the line voltage on the supply side has the value of the nominal system voltage and that the nominal system voltage on the load side is switched off, then the difference detector generates a reset signal for the operating time counter so as to be able to monitor a new test interval when the operating time counter is restarted.

With regard to a device and in correspondence to the method according to the invention in the second embodiment, the task is further solved by a monitoring device that comprises a time measuring device for registering a time period that is independent of the operating time of the residual current protective device, and a limit comparator for detecting an exceedance of an adjustable time period limit and for sending out a trigger signal for an alarm report.

This implementation thus comprises a time measuring device which is not coupled to the operating time of the residual current protective device and which thus is independent of the system voltage. The current value of the time measuring device corresponds to the time period lapsed since the last restart (reset). The limit comparator compares said current value to the preset time period limit and sends out a trigger signal for an alarm report if the time period limit has been exceeded.

In an advantageous implementation, the monitoring device comprises a vibration detector for detecting vibrations of components of the residual current protective device, said vibrations occurring in connection with the trigger process, and for generating a reset signal for the time measuring device.

Instead of a detection of a trigger process of the residual current protective device which detection is dependent on the line voltages, the detection in this second embodiment is based on the detection of component vibrations, which inevitably occur when the residual current protective device is triggered. Said vibrations and the resulting sound waves are received mechanically and/or acoustically by a vibration detector. If occurring vibrations or sound waves can be associated with a trigger process by means of suitable evaluations, i.e. if a trigger process is detected directly, then the vibration detector generates a reset signal for the time measuring device so as to be able to monitor the temporally subsequent test interval.

Preferably, the vibration detector is configured to receive component vibrations directly or to receive sound waves caused by the component vibrations. The component vibrations can be directly received mechanically by means of a vibration receiver or the sound waves can be detected acoustically by means of microphones.

Furthermore, the second embodiment comprises an energy supply unit for providing the energy for the monitoring device. Since this embodiment is not electrically coupled to the residual current protective device, the monitoring device in this embodiment obtains its energy from an own energy supply unit.

Both embodiments of the monitoring device comprise an alarm generator, which receives the trigger signal of the limit comparator and sends out and/or transmits an alarm report. In this context, the alarm generator can be implemented as a warning device for sending out acoustically and/or optically perceptible signals. Also, an implementation as a switching contact and/or as a wired interface and/or as a wireless interface is advantageous for transmitting information regarding a repetitive test to be performed.

### BRIEF DESCRIPTION OF THE DRAWINGS

Other advantageous implementation features result from the following description and from the drawing, which illustrates preferred embodiments of the invention with the aid of examples.

FIG. 1: shows a functional block diagram of the monitoring device according to the invention in a first embodiment,

FIG. 2: shows a functional block diagram of the monitoring device according to the invention in a second embodiment.

### DETAILED DESCRIPTION OF THE EXAMPLE EMBODIMENTS

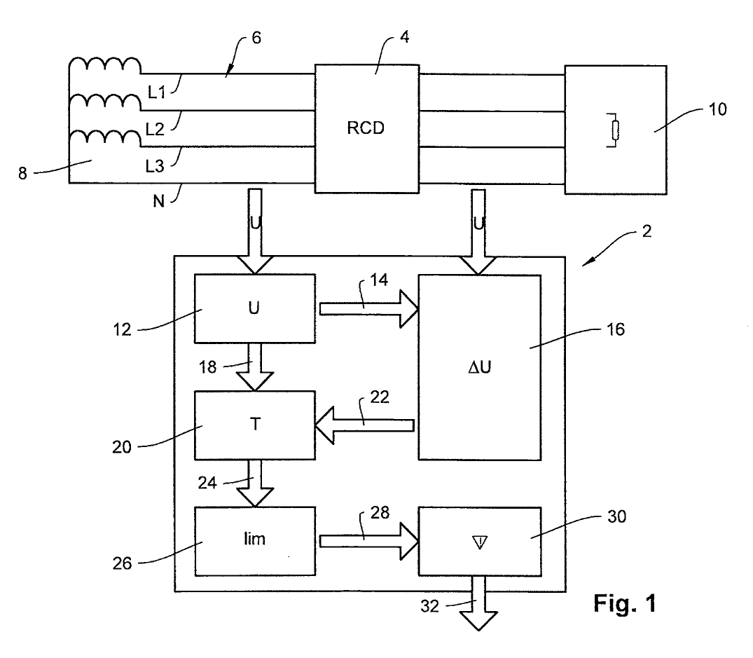

FIG. 1 shows a functional block diagram of a first embodiment of a monitoring device 2 according to the invention in conjunction with a residual current protective device 4 to be tested in a multiphase power supply system 6. The residual current protective device 4 is arranged in the power supply system 6 between a supply point 8 of the power supply system 6 and a load 10.

The monitoring device 2 comprises a voltage detector 12, which taps a voltage on one of the active conductors L1, L2, L3 or N of the power supply system 6 at the supply side of the residual current protective device 4 and transmits a status information 14 concerning the voltage state on the supply side (nominal system voltage present/not present) to a difference detector 16 of the monitoring device 2. If a nominal system voltage is detected on the supply side, the voltage detector 12 sends an enabling signal 18 to an operating time counter 20 of the monitoring device 2 so as to enable the counting process. The difference detector 16 detects whether a nominal system voltage is present on the load side, too, and sends a reset signal 22 to the operating time counter 20 to restart the latter in case a nominal system voltage is detected on the supply side, but no nominal system voltage is present at the load side. The operating time counter 20 transmits the current counter reading 24 to a limit comparator 26 of the monitoring device 2. If the limit comparator 26 finds that the current counter reading 24 exceeds a preset operating time limit, the limit comparator 26 sends out a trigger signal to an alarm generator 30 of the monitoring device 2 so as to cause the latter to send out an alarm report 32 or to transmit the information concerning an upcoming repetitive test.

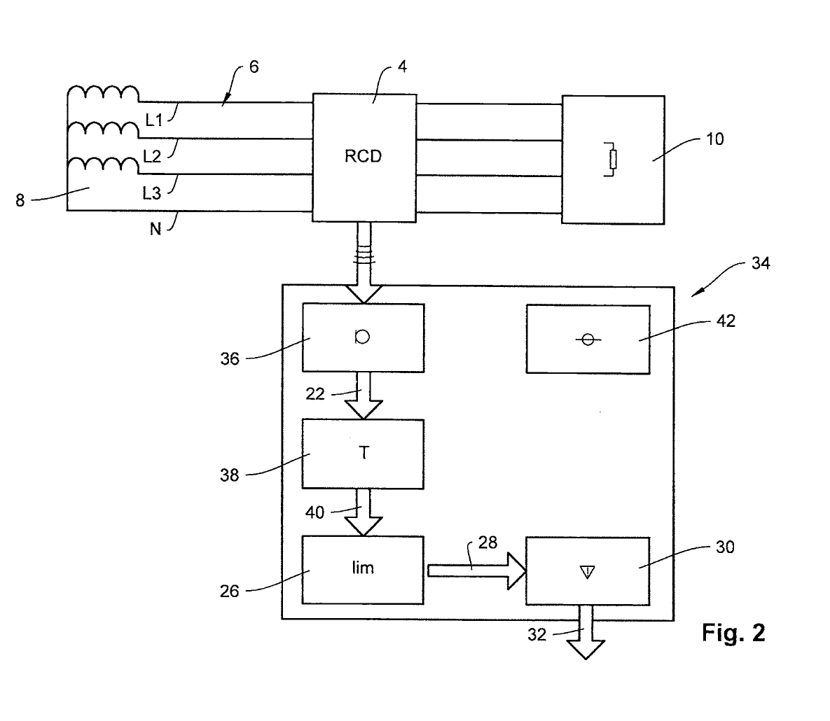

In FIG. 2, a functional block diagram of a second embodiment of a monitoring device 34 according to the invention is illustrated in conjunction with a residual current protective device 4 to be tested in a multiphase power supply system 6. Like in the first embodiment in FIG. 1, the residual current protective device 4 is arranged in the power supply system 6 between the supply point 8 of the power supply system 6 and the load 10.

The monitoring device 34 comprises a vibration detector 36, which receives vibrations of components of the residual current protective device 4, said vibrations occurring during a trigger process of the residual current protective device 4, or the sound waves caused by said vibrations. If in this manner a trigger process of the residual current protective device 4 is positively detected, the vibration detector 36 generates a reset signal 22 for a time measuring device 38. In this context, the time period measured by the time measuring device 38 is independent of the operating time of the residual current protective device 4 and represents an autonomous device that is not coupled to the residual current protective device 4—apart from the mechanical/acoustic coupling via the vibration detector 36 during a component vibration.

The current value 40 of the time measuring device 38 is fed to a limit comparator 26, which compares said current value to a preset time limit and, in analogy to the first embodiment, sends out a trigger signal 28 to an alarm generator 30 for further processing if the time limit has been exceeded.

In contrast to the first embodiment, in which the monitoring device 2 obtains its energy directly on the supply side from the power supply system 6, the monitoring device 34 in the second embodiment, for lack of an electrical coupling to the power supply system 6, comprises its own energy supply unit 42 for providing energy for the monitoring device 34.

1. A method for monitoring a test interval for a residual current protective device said method comprising:
measuring an operating time of a residual current protective device, for which a test interval is being monitored;
triggering an alarm report if the measured operating time exceeds an operating time limit; and
restarting the operating time measurement upon detection of a trigger process of the residual current protective device.

2. The method according to claim 1, in which a line voltage is measured on a supply side and a line voltage is measured on a load side of the residual current protective device and that the restart of the operating time measurement takes place as a function of the measured line voltages.

3. The method according to claim 2, in which the restart of the operating time measurement takes place if an evaluation of the measured line voltages reveals that the line voltage on the supply side has the value of the nominal system voltage and the nominal system voltage on the load side is switched off.

4. The method according to claims 1, in which the operating time limit is adjustable.

5. A method for monitoring a test interval for a residual current protective device, said method comprising:
measuring a time period that is independent of the operating time of a residual current protective device, for which a test interval is being monitored;
triggering an alarm report if the measured time period exceeds a time period limit; and
restarting the time measurement upon detection of a trigger process of the residual current protective device.

6. The method according to claim 5, in which for detecting the trigger process of the residual current protective device, vibrations of components of the residual current protective device are detected, said vibrations occurring in connection with the trigger process.

7. The method according to claim 5, in which the time period limit is adjustable.

8. The method according to claim 1, in which an acoustically and/or optically perceptible signal is sent out as the alarm report.

9. The method according to claim 1, in which when an alarm report is triggered, a switching contact is actuated and/or a wired interface and/or a wireless interface is activated.

10. A monitoring device for maintaining a test interval for a residual current protective device, said device comprising:
an operating time counter for measuring an operating time of the residual current protective device for which a test interval is being monitored; and
a limit comparator for detecting an exceedance of an adjustable operating time limit and sending out a trigger signal for an alarm report.

11. The monitoring device according to claim 10, including a voltage detector detecting a line voltage on a supply side of the residual current protective device, a difference detector for detecting a difference in the line voltages between the supply side and a load side of the residual current protective device and generating a reset signal for resetting the operating time counter.

12. A monitoring device for maintaining a test interval for a residual current protective device, said device comprising:
a time measuring device for registering a time period that is independent of the operating time of a residual current protective device for which a test interval is being monitored; and
a limit comparator for detecting an exceedance of an adjustable time period limit and for sending out a trigger signal for an alarm report.

13. The monitoring device according to claim 12, including a vibration detector detecting vibrations of components of the residual current protective device, said vibrations occurring in connection with the trigger process, and for generating a reset signal for the time measuring device.

14. The monitoring device according to claim 12, in which the vibration detector is configured to directly absorb component vibrations or to absorb sound waves caused by said component vibrations.

15. The monitoring device according to claim 12, including an energy supply unit providing energy for the monitoring device.

16. The monitoring device according to claim 10, including an alarm generator, which receives the trigger signal of the limit comparator and sends out or transmits an alarm report.

17. The monitoring device according to claim 16, in which the alarm generator is warning device sending out at least one of an acoustic signal and an optic signal.

18. The monitoring device according to claim 17, in which the alarm generator includes at least one of a switching contact, a wired interface, and a wireless interface.

19. The monitoring device according to claim 12, including an alarm generator, which receives the trigger signal of the limit comparator and sends out or transmits an alarm report.

20. The monitoring device according to claim 19, in which the alarm generator is a warning device sending out at least one of an acoustic signal and an optic signal.
